(19) United States
(12) Patent Application Publication
(10) Pub. No.: US 2026/0062793 A1
(43) Pub. Date: Mar. 5, 2026

(54) CRUCIBLE, EVAPORATION SOURCE, EVAPORATION METHOD, EVAPORATION SYSTEM, AND METHOD OF MANUFACTURING A DEVICE

(71) Applicant: Applied Materials, Inc., Santa Clara, CA (US)

(72) Inventors: Takashi ANJIKI, Aschaffenburg (DE); Sebastian FRANKE, Hanau (DE)

(21) Appl. No.: 19/378,291

(22) Filed: Nov. 3, 2025

Related U.S. Application Data
(62) Division of application No. 18/272,841, filed on Jul. 18, 2023, now abandoned.

(51) Int. Cl. C23C 14/24; C23C 14/12; C23C 14/54; H10K 71/16

(52) U.S. Cl. CPC C23C 14/243; C23C 14/12; C23C 14/54; H10K 71/164

(57) ABSTRACT

A crucible to evaporate a material is described. The crucible includes a first material compartment configured to contain material to be evaporated, a first heater to heat the first material compartment, a second material compartment configured to contain material to be evaporated, and a second heater to heat the second material compartment. A vapor guiding compartment is provided. The vapor guiding compartment has a first opening providing a first fluid communication path between the first material compartment and the vapor guiding compartment and has a second opening providing a second fluid communication path between the second material compartment and the vapor guiding compartment. Further, the vapor guiding compartment has a third opening connectable to a vapor distributor. The crucible further includes a third heater to heat the vapor guiding compartment.

### CROSS-REFERENCE TO RELATED APPLICATIONS

This application is a divisional of U.S. Patent Application Serial No. 18/272,841, filed July 18, 2023, which is a national stage of International Patent Application Serial No. PCT/IB2021/051285, filed February 16, 2021, each of which are herein incorporated by reference.

### TECHNICAL FIELD

The present disclosure relates to apparatuses, sources and methods for material evaporation, e.g. evaporation of organic material. Embodiments of the present disclosure relate in particular to methods, sources and apparatuses for evaporating a material and particularly an organic material for creating organic light-emitting diodes (OLEDs) in a vacuum deposition system. Particularly, embodiments of the present disclosure relate to a crucible, an evaporation source, an evaporation method, a vacuum processing system, and a method of manufacturing a device.

### BACKGROUND

Techniques for depositing a layer on a substrate include the evaporation of a material in an evaporation source. For instance, evaporation sources are a tool for the production of organic light-emitting diodes (OLED) and other electronic or optic devices including a stack of deposited materials. OLEDs are a special type of light-emitting diode in which the emissive layer comprises a thin-film of certain organic compounds. Organic light emitting diodes (OLEDs) are used in the manufacture of television screens, computer monitors, mobile phones, and other hand-held devices, etc., for displaying information. OLEDs can also be used for general space illumination. The range of colors, brightness, and viewing angles possible with OLED displays is greater than that of traditional LCD displays because OLED pixels directly emit light and do not involve a back light. Therefore, the energy consumption of OLED displays is considerably less than that of traditional LCD displays. Further, the fact that OLEDs can be manufactured onto flexible substrates results in further applications. Evaporation sources can also be used for the deposition of other material layers, e.g. metal layers, on substrates, such as on glass substrates or on semiconductor wafers.

Evaporation sources typically include an evaporation apparatus that is configured to evaporate a source material by heating the source material to a temperature at or above the evaporation temperature of the source material. The evaporated source material can propagate into a vapor distribution pipe that is configured for directing the evaporated source material onto a substrate.

During processing, the substrate can be supported on a carrier configured to hold the substrate. For example, the substrate may be held in alignment with a mask. The vapor from the evaporation source is directed toward the substrate, for example, through the mask, to create a film such as a patterned film on the substrate. One or more materials may be deposited onto the substrate to create small pixels that can be addressed individually to create functional devices such as full color displays.

An inner volume of the evaporation apparatus can be heated for evaporating the source material. The source material can be arranged in solid form inside the evaporation apparatus, e.g. as a powder or as a granulate. However, it is challenging to ensure a predetermined evaporation rate of the source material over an extended time. Further, source materials can be temperature sensitive, such that there is a risk of chemical reactions related to the source material in the evaporation apparatus if the source material is exposed to the high temperatures inside the evaporation apparatus, particularly over an extended time. If any impurity caused by any chemical reaction e.g. decomposed OLED material reaches the substrate, it can lead to a reduction of OLED device luminous efficiency and lifetime. In case any chemical reaction which generates an impurity having lower vapor pressure than the original material occurs e.g. polymerization and oxidization, at least a part of the impurity stays in the crucible and may cover the surface area of the original material. This results in higher temperature to maintain the predetermined evaporation rate, therefore the risk of deterioration of OLED device performance can be increased.

In light of the above, it would be beneficial to provide an improved evaporation method and an improved evaporation apparatus that ensure a high-quality deposition of evaporated materials, particularly for the manufacture of OLED devices. Specifically, the risk of containing impurities in the substrate should be reduced while ensuring a predetermined evaporation rate over an extended time.

### SUMMARY

In light of the above, a crucible, an evaporation method, an evaporation apparatus, an evaporation system, and an evaporation source according to the independent claims are provided. Further advantages, features, aspects and details are apparent from the dependent claims, the description and drawings.

According to an embodiment, a crucible to evaporate a material is provided. The crucible includes a first material compartment configured to contain material to be evaporated, a first heater to heat the first material compartment, a second material compartment configured to contain material to be evaporated, and a second heater to heat the second material compartment. A vapor guiding compartment is provided. The vapor guiding compartment has a first opening providing a first fluid communication path between the first material compartment and the vapor guiding compartment and has a second opening providing a second fluid communication path between the second material compartment and the vapor guiding compartment. Further, the vapor guiding compartment has a third opening connectable to a vapor distributor. The crucible further includes a third heater to heat the vapor guiding compartment.

According to an embodiment, an evaporation source is provided. The evaporation source includes a crucible according to any of the embodiments described herein and the vapor distributor in fluid communication with the third opening.

According to an embodiment, an evaporation method is provided. The method includes providing a source material to be evaporated in a first material compartment of a crucible; heating the first material compartment to evaporate the source material generating evaporated source material while a second material compartment of the crucible is in an idle state; guiding the evaporated source material from the first material compartment to a vapor distributor; heating the second material compartment to evaporate condensed source material in the second material compartment generating evaporated source material; guiding the evaporated source material from the second material compartment to the vapor distributor; and switching the first material compartment to an idle state.

According to an embodiment, an evaporation source is provided. The evaporation source includes a crucible and a controller having a processor and a memory storing instructions that, when executed by the processor, cause the evaporation source to perform an evaporation method according to embodiments of the present disclosure.

According to an embodiment, method of manufacturing a device having a layer of organic material is provided. The method includes operating a crucible according to an evaporation method of any of the embodiments of the present disclosure and depositing a layer of organic material on a substrate.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A to 1C show schematic sectional views of a crucible having a first material compartment and a second material compartment, particularly a second material compartment separated from the first material compartment, according to embodiments described herein and showing three subsequent control stages of an evaporation apparatus according to embodiments described herein for illustrating an evaporation method;

FIG. 2 schematically shows a schematic view of an evaporation source according to embodiments described herein;

FIGS. 3A and 3B show schematic sectional views of crucibles according to embodiments described herein, illustrating conductance adjustment of condensing material in a material compartment;

FIG. 4 schematically shows a schematic view of an evaporation source according to embodiments described herein;

FIG. 5 shows a graph illustrating an evaporation method with two material compartments of a crucible;

FIG. 6 shows a flow chart of an evaporation method according to embodiments described herein; and

FIG. 7 shows a schematic view of a vacuum processing system according embodiments of the present disclosure.

### DETAILED DESCRIPTION OF THE EMBODIMENTS

Reference will now be made in detail to the various embodiments of the disclosure, one or more examples of which are illustrated in the figures. Within the following description of the drawings, same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Many source materials, particularly organic source materials and other material compositions are temperature sensitive, such that chemical reactions related to the source material may occur when exposing the source material to elevated temperatures over an extended time. Especially for organic materials, the temperature causing any chemical reaction may be close to the evaporation temperature of the material, such that there is a considerable risk to create impurity of the organic material inside the crucible. For example, the risk to create impurity may already considerably increase when the temperature inside the crucible increases by several degrees, particularly when the source material is exposed to the elevated temperature over an extended time. Accordingly, it would be beneficial to provide evaporation apparatuses and evaporation methods that reduce the risk of containing impurities in the substrate and improve the quality of the deposited material.

Embodiments of the present disclosure provide an improved crucible, evaporation source and method of evaporation, particularly for increased system run times of 100 hours or more, or even 200 hours or more. For a predetermined evaporation rate, the increase in crucible temperature and/or material temperature gets steeper over time. Since the temperature limit or thermal exposure limit of the material may be reached, i.e. the temperature would be increased in a range that may result in increasing any impurity e.g. decomposed OLED material in the substrate, the system run time can be limited. It has been found that one or more of polymerization of organic material, oxidization of organic material, or degradation of organic material by thermal exposure may occur. This may generate an impurity having lower vapor pressure than the original OLED material resulting in a so-called “skin” that reduces the material surface area contribution to evaporation. The internal conductance for the material surface can be reduced, for example, close to the total source conductance, wherein the material would need to be heated to a higher temperature to keep the vapor pressure(or the predetermined evaporation rate) resulting in the steeper temperature rise.

For example, a 10°C temperature increase may approximately double the evaporation rate. Yet, close to the decomposition onset, the decomposition rate may approximately quadruple. Further, close to the decomposition onset, a doubling of the exposure time may approximately triple the decomposition rate.

Embodiments described herein relate inter alia to a crucible, and evaporation source, an evaporation apparatus for evaporating a source material and for directing the evaporated source material toward a substrate for depositing the evaporated source material on the substrate. According to an embodiment, a crucible to evaporate a material is provided. The crucible includes a first material compartment configured to contain material to be evaporated and a first heater to heat the first material compartment. The crucible further includes a second material compartment configured to contain material to be evaporated and a second heater to heat the second material compartment. A vapor guiding compartment is provided. The vapor guiding compartment has a first opening providing a first fluid communication path between the first material compartment and the second vapor guiding compartment and having a second opening providing a second fluid communication path between the second material compartment and the vapor guiding compartment, the vapor guiding compartment further having a third opening connectable to a vapor distributor. Further, the crucible includes a third heater to heat the vapor guiding compartment.

An “evaporation source” or a “crucible” as used herein can be understood as an apparatus configured for evaporating a source material by heating the source material to a temperature at or above the evaporation temperature of the source material. The “evaporation temperature” can be understood as a temperature at which the source material vaporizes, i.e. transitions into the vapor phase. In some embodiments, the evaporation temperature is a temperature in a range between 200°C and 400°C, particularly between 250°C and 350°C.

The source material may be provided in the crucible of the evaporation apparatus in a solid form, e.g. as a powder or a granulate. The source material can be an organic material, particularly an organic material for the manufacture of OLED devices. Typical organic materials have an evaporation temperature in a range between 200°C and 400°C. In other words, under vacuum conditions, typical organic materials evaporate at an evaporation temperature between 200°C and 400°C.

According to embodiments described herein, material evaporated from a first material compartment can condense in a second material compartment, wherein the purification process occurs. Accordingly, the so-called “skin”-effect can be reduced by the condensation. Evaporation from the first material compartment and the second material compartment can be repeatedly switched. Accordingly, after purification has occurred during condensation in the second material compartment, the second material compartment can be utilized for evaporation and condensation occurs in the first material compartment.

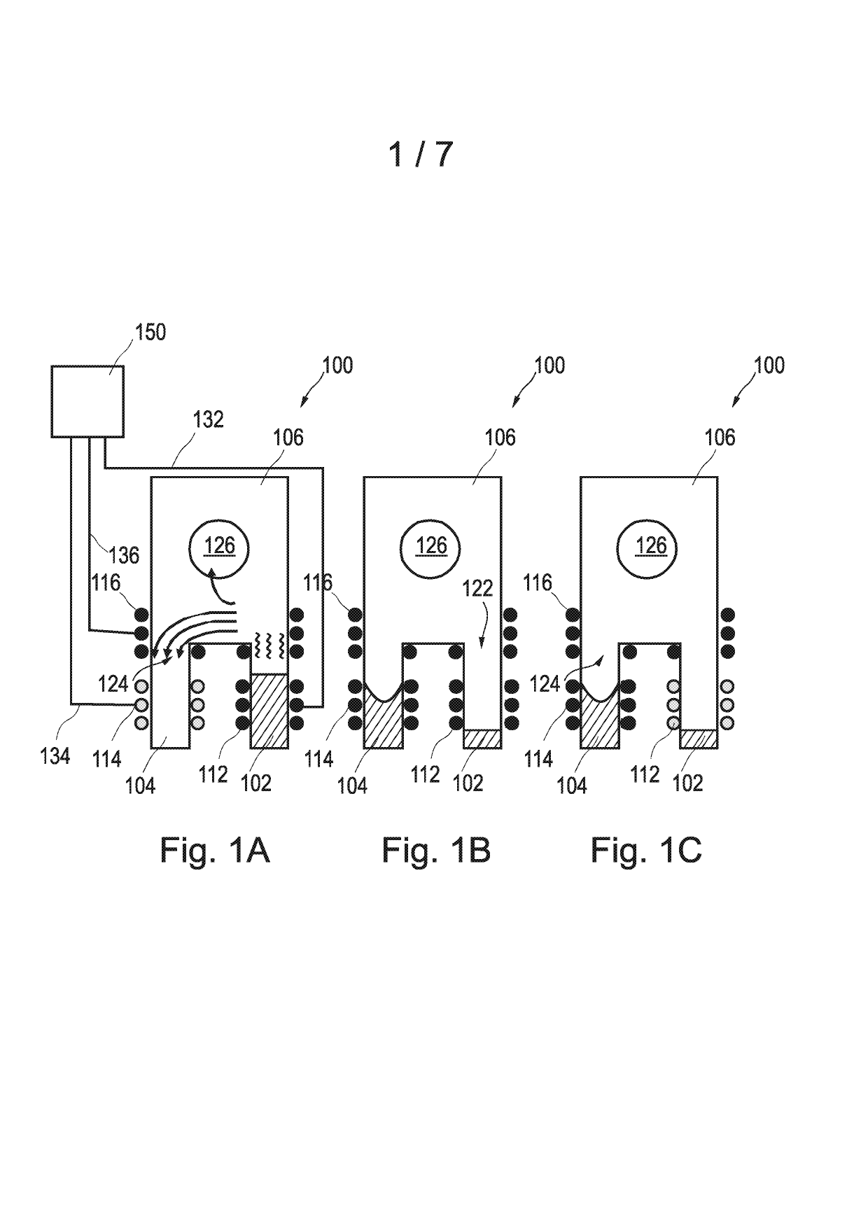

FIGS. 1A to 1C show crucible 100 during different operation scenarios. FIG. 1A shows a first material compartment 102. The first material compartment 102 is heated by the first heater 112. Further, a second material compartment 104 is provided. The second material compartment can be heated by a second heater 114. A vapor guiding compartment 106 is provided. The vapor guiding compartment 106 is heated by a third heater 116. The heaters according to embodiments described herein can surround the respective compartments and/or can be provided at an outside of the wall of the respective compartment.

FIG. 1A shows source material to be evaporated in the first material compartment 102. In FIG. 1A, the first heater 112 is switched on, the second heater 114 is switched off, and the third heater 116 is switched on. The second material compartment 104 is in an idle state. The vapor guiding compartment 106 has a first opening 122 or passage providing a first fluid communication path between the first material compartment 102 and the vapor guiding compartment 106. Vapor generated during operation of an active first heater 112 is guided into the vapor guiding compartment 106 through the first opening, as illustrated in FIG. 1A.

A portion of the vapor generated by the heating of the first material compartment 102 with the first heater 112 is guided to a third opening 126. The third opening 126 is connectable to a vapor distributor to guide the evaporated material to a substrate to be processed. A portion of the evaporated source material enters the second material compartment 104, for example, through the second opening 124 of the vapor guiding compartment. The second opening 124 provides a passage for a second fluid communication path between the second material compartment and the vapor guiding compartment. The evaporated source material condenses in the second material compartment 104. The condensation provides for the purification process. Condensation in the vapor guiding compartment may be avoided by activating the third heater 116.

FIG. 1B shows a situation in which the first material compartment has been heated, i.e. operated for some time. The amount of source material in the first material compartment 102 has been reduced due to the evaporation. The amount of source material in the second material compartment 104 has been increased due to the condensation. At a time at which material decomposition may occur by the heating of the first material compartment and/or evaporating from the first material compartment 102, the second heater 114 is activated and material that has accumulated in the second material compartment 104 is evaporated for operating the crucible 100 for substrate processing. FIG. 1B shows the status at which both the first heater 112 and the second heater 114 are operated.

As shown in FIG. 1C, the first heater 112 can be switched off after the transfer of the evaporation of the crucible has been switched from evaporation in the first material compartment 102 (see FIG. 1A) to evaporation in the second material compartment 104. The status shown in FIG. 1C results in evaporation of source material in the second material compartment 104, wherein a portion of the evaporated material is guided towards the vapor distributor through the third opening 126 of the crucible 100. The first heater 112 is inactive, such that material evaporated from the second material compartment may condense in the first material compartment. A purification process occurs in the first material compartment, i.e. inferior operation conditions that may occur based on the skin-effect after operation as shown in FIG. 1A may be improved by adding the code condense source material in the first material compartment.

Embodiments of the present disclosure provide an organic material evaporation source and evaporation method with a purification process, wherein a process such as polymerization, oxidization or degradation of the organic material, which may, for example, lead to the so-called “skin”-effect can be at least partially healed. The runtime of the crucible and the corresponding source can be increased.

According to some embodiments, which can be combined with other embodiments described herein, the organic material can be filled separately in the separate material compartments, for example, the first material compartment 102 and the second material compartment 104. The material compartments have dedicated heating elements or heaters for each of the material compartments. While one material compartment is used to vaporize the material, the other material compartment can collect a portion or fraction of the vapor. The collected vapor is condensed back into a solid phase or liquid phase while the remaining vapor can be guided to the substrate area. The role of the material compartments can be repeatedly switched. For example, after operation as shown in FIG. 1C, when material has been collected in the first material compartment 102, an intermediate operation condition as shown in FIG. 1B can be provided to move to the initial operation condition as shown in FIG. 1A. The process may then start from the beginning as described above.

The common concept to mitigate organic material degradation by having different temperature zones or a temperature gradient in the crucible to minimize the thermal exposure may reduce the thermal exposure. However, a purification according to embodiments of the present disclosure is not provided by such a concept of a temperature gradient. A crucible, an evaporation source, and/or a method of evaporating material according to embodiments described herein enables to purify a part of the material in parallel with the deposition of vapor on the substrate. At least a portion of the thermal exposure history can be reset by the purified material, particularly it can be reset continuously by switching the role of the compartments. A reduced evaporation area due to reaction by thermal exposure such as polymerization or oxidation can be reset, i.e. the evaporation area can be increased again due to the purification. According to an example of an organic material for a green dopant, the runtime can be increased by about a factor of four.

According to embodiments of the present disclosure, evaporation from the crucible can be provided by switching between heating a first material compartment and heating a second material compartment and vice versa. According to some embodiments, which can be combined with other embodiments described herein, an intermediate operation condition, as for example shown in FIG. 1B, wherein the first heater of the first material compartment and a second heater of second material compartment are switched on, can be provided. Alternatively, switching may occur without an intermediate operation condition. The intermediate operation condition may advantageously provide a better current role of the evaporation rate of the crucible for substrate processing.

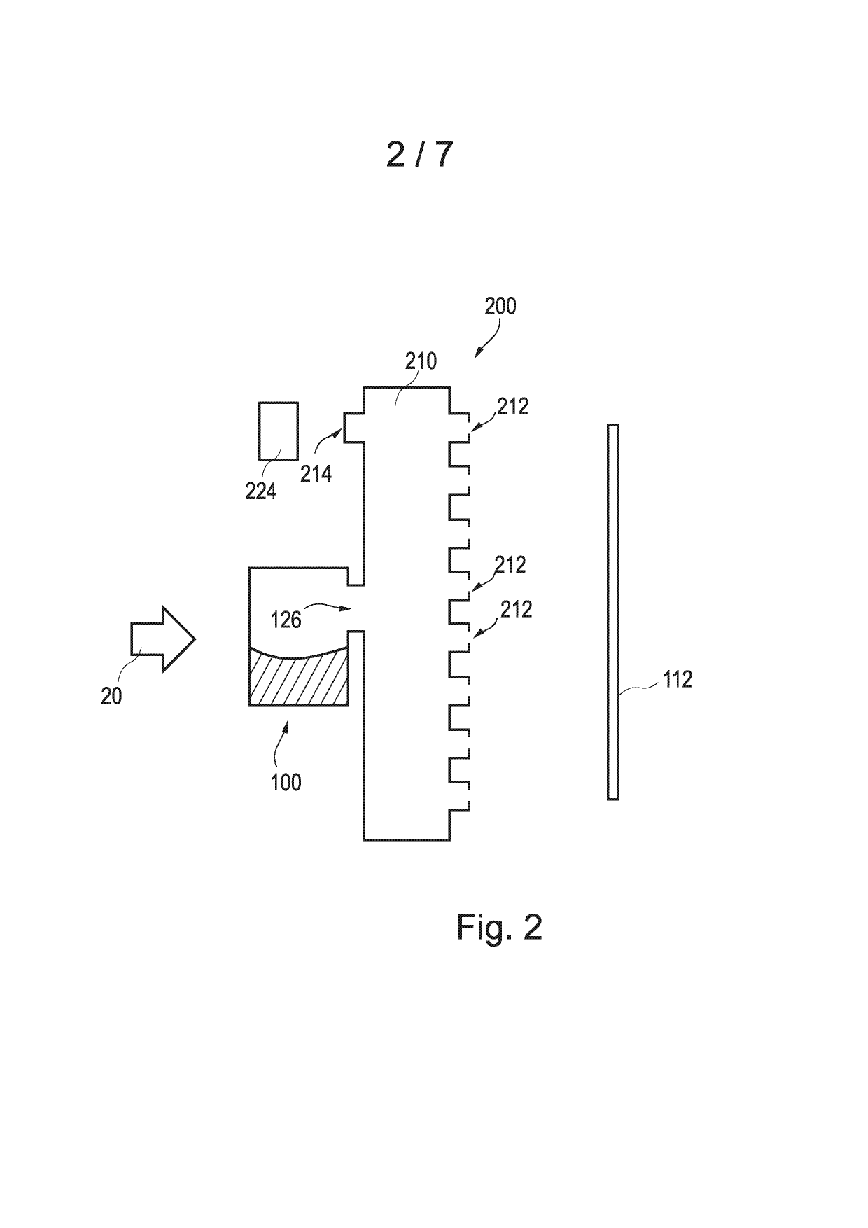

According to some embodiments, which can be combined with other embodiments described herein, the switching may be triggered by at least one of the material characterization of the evaporated material, the temperature of the active material compartment, and the fill level of the active material compartment. For example, switching from one material compartment to the other material compartment may occur if the active feature temperature gets close to the temperature limit and/or the active material compartment gets close to an empty fill level. As another example, that may additionally or alternatively be used, is the ratio of an evaporation rate that may be measured at the evaporation source (see, for example, FIG. 2) and the temperature of the active material compartment.

The plurality of heaters, such as the first heater, the second heater and the third heater as described with respect to FIGS. 1A to 1C, may include several heating elements or heaters, respectively. As shown exemplarily in FIG. 1A, a controller 150 connected to the first heater 112 with a first wire 132 is configured to control the first heater. The controller 150 may further be connected to the second heater 114 with second wire 134 and can be configured to control the second heater. The controller 150 may further be connected to the third heater 116 with third wire 136 and can be configured to control the third heater.

In some embodiments, the controller may switch from operating the first heater to operating the second heater and vice versa, optionally with an intermediate operation condition, wherein both heaters are operated.

A “heater” as used herein, may refer to one or more heating elements arranged next to a specific compartment of the crucible that can be controlled by the controller to achieve a predetermined temperature in the specific compartment. A “heater” may refer to a plurality of heating elements configured to act as a heater for one sub-volume of the crucible.

FIG. 2 shows a schematic sectional view of an evaporation source 200 according to embodiments described herein. The evaporation source 200 includes a crucible 100 according to any of the embodiments described herein, and a vapor distributor 210 in fluid communication with the crucible 100, e.g. via the third opening 126. The arrow 20 indicates the direction of the view on the crucible 100 shown in FIGS. 1A to 1C. The vapor distributor 210 includes a plurality of vapor nozzles (nozzle openings 212) for directing the evaporated source material toward a substrate 10.

The vapor distributor 210 may be connected to the vapor release port of the crucible, i.e. the third opening 126, such that the evaporated source material from each of the material compartments of the crucible can propagate into the vapor distributor 210.

A “vapor distributor” or “vapor distribution assembly” can be understood as an assembly configured for directing evaporated material, particularly one or more plumes of evaporated material, toward the substrate 10. For example, the vapor distributor or vapor distribution assembly may include a distribution pipe which can be an elongated tube. For instance, a distribution pipe may provide a line source with a plurality of vapor nozzles, which are arranged in at least one line along the length of the pipe.

In some embodiments, the vapor distributor can be a linear distribution showerhead. The linear distribution showerhead may extend in an essentially vertical direction, such that an essentially vertically oriented substrate can be coated by the evaporation source. A linear distribution showerhead can have a hollow space or tube in which the evaporated material can be guided, for example from the evaporation apparatus to the plurality of vapor nozzles. Heating elements may be provided for heating an inner volume of the vapor distribution assembly to a temperature above the evaporation temperature, in order to avoid a condensation of the evaporated source material in the vapor distribution assembly.

The term “substrate” as used herein may particularly embrace substantially inflexible substrates, e.g., a wafer, slices of transparent crystal such as sapphire or the like, or a glass plate. In some embodiments, the substrate may be a semiconductor wafer. However, the present disclosure is not limited thereto, and the term “substrate” may also embrace flexible substrates such as a web or a foil.

The term “substrate” as used herein encompasses large area substrates. For instance, a “large area substrate” can have a main surface with an area of 0.5 m² or larger, particularly of 1 m² or larger. In some embodiments, a large area substrate can be GEN 4.5, which corresponds to about 0.67 m² of substrate (0.73m x 0.92m), GEN 5, which corresponds to about 1.4 m² of substrate (1.1 m x 1.3 m), GEN 7.5, which corresponds to about 4.29 m² of substrate (1.95 m x 2.2 m), GEN 8.5, which corresponds to about 5.7 m² of substrate (2.2 m x 2.5 m), or even GEN 10, which corresponds to about 8.7 m² of substrate (2.85 m × 3.05 m). Even larger generations such as GEN 11 and GEN 12 and corresponding substrate areas can similarly be implemented.

As shown in FIG. 2, a further opening 214 may be provided in the vapor distributor 210. The further opening may direct a portion of the vapor to a deposition rate monitor 224. For example, the deposition rate monitor may include an oscillation quartz microbalance (QCM) and/or an optical inspection device measuring the amount of vapor material with a light source and a light detector.

According to one embodiment, an evaporation source is provided. The evaporation source includes a crucible according to any of the embodiments described herein. The evaporation source further includes the vapor distributor in fluid communication with the third opening of the crucible, particularly the third opening of the vapor guiding compartment of the crucible. For example, the vapor distributor can have an inlet port connected to the third opening, the inlet port is provided between a first end of the vapor distributor and a second end of the vapor distributor. In FIG.2, the vapor distributor has an upper end of the tube or pipe (i.e. first end) and the lower end of the tube or pipe (i.e. a second end). The inlet port of the vapor distributor can be provided between the first end and the second end, for example, adjacent to approximately a center or at the center of the vapor distributor. Particularly for long line sources, a more uniform vapor pressure can be provided in the vapor distributor if the crucible is connected between the first end and the second end, for example, at about the center of the vapor distributor. As described above, according to some embodiments, which can be combined with other embodiments described herein, the vapor distributor may include a plurality of outlet nozzles to guide material vapor to a substrate.

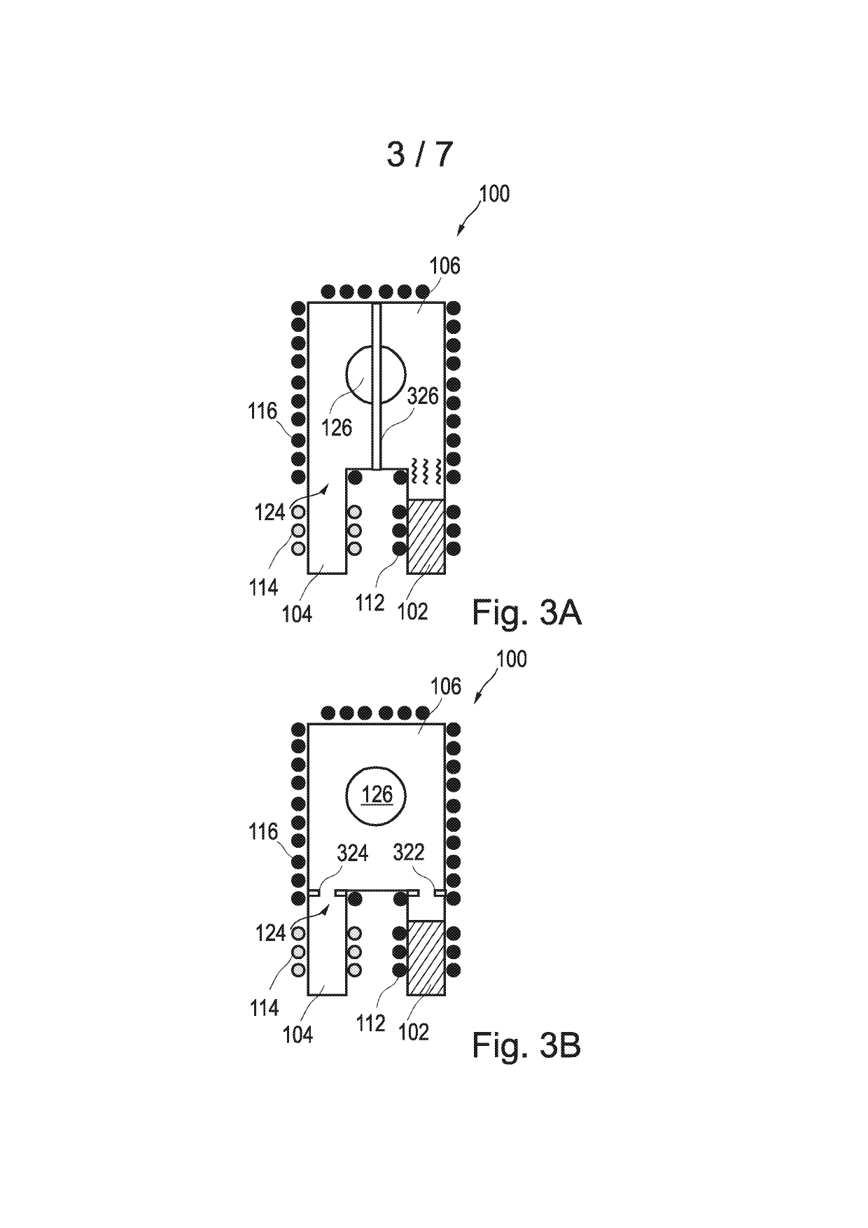

According to some embodiments, which can be combined with other embodiments described herein, the ratio between a deposition rate on the substrate and a purification speed can be adjusted by the crucible design. FIGS. 3A and 3B show two embodiments to adjust the ratio between the deposition rate and the purification speed, which may be utilized individually or in combination with each other. FIGS. 3A and 3B show a first material compartment 102 with a first heater 112, a second material compartment 104 with a second heater 114 and the vapor guiding compartment 106 with a third heater 116. In FIG. 3A, a partition wall 326 is provided in the vapor guiding compartment. The partition wall 326 can limit the amount of material that is collected in one material compartment while source material is evaporated from the other material compartment. According to some embodiments, which can be combined with other embodiments described herein, the partition wall can be provided to define a fluid conductance between the first material compartment and the second material compartment. According to optional implementations, the partition wall can include one or more openings, for example, slit openings to further define the fluid conductance between the material compartments.

FIG. 3B includes a first orifice 322, for example, at the first opening 122. Further, the crucible 100 can include a second orifice 324, for example, at the second opening 124, the openings being exemplarily referenced in FIGS. 1a to 1C. According to some embodiments, which can be combined with other embodiments described herein, at least one of a first orifice in the first fluid communication path and a second orifice in the second fluid communication path are provided.

According to some embodiments, a partition wall as described herein and/or an orifice as described herein may be utilized to control and/or adjust the ratio between the deposition rate and the purification speed. For example, the ratio can be adjusted depending on a predetermined runtime of one cycle and may be limited by or adjusted in light of the material property and the total runtime requirement of the crucible.

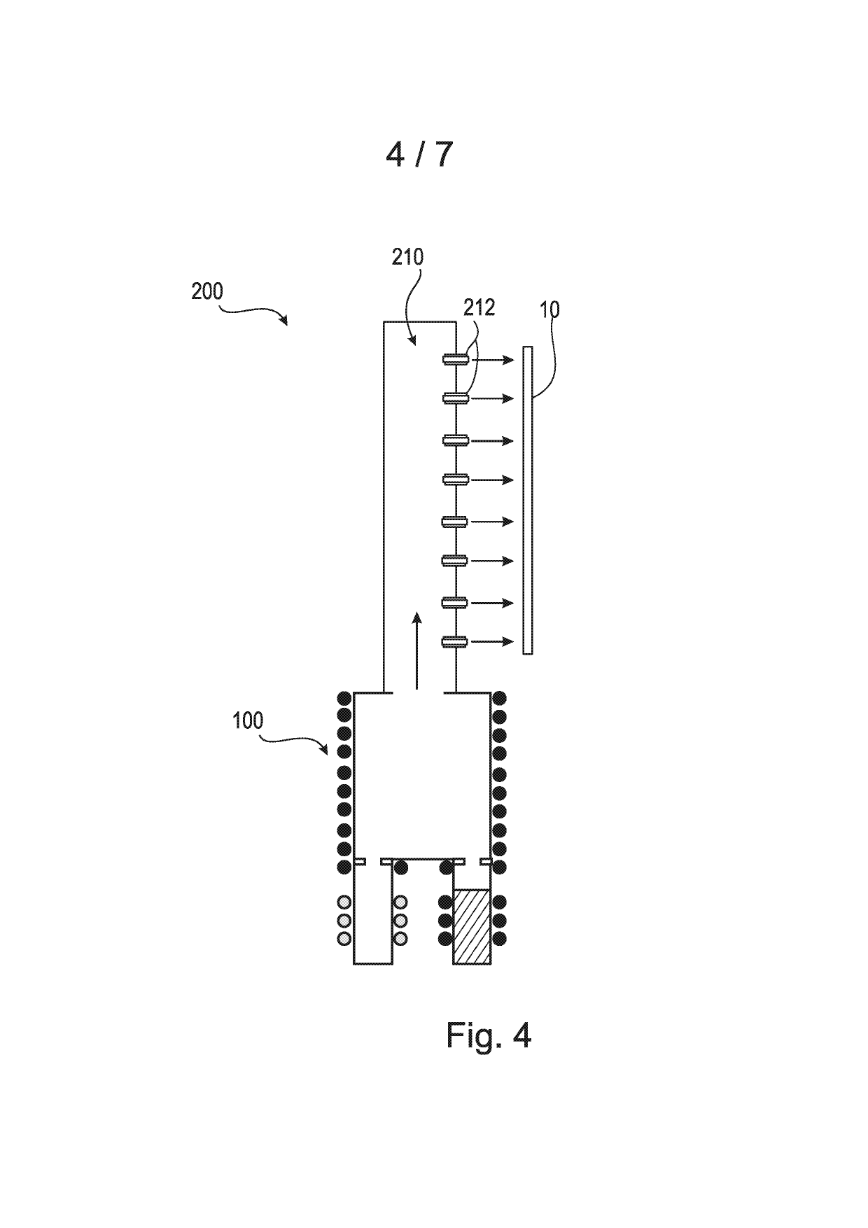

FIG. 4 shows another embodiment of an evaporation source 200. The evaporation source 200 shown in FIG. 4 includes a vapor distributor 210 having a plurality of nozzle openings 212 for directing vapor of the source material to the substrate 10. Contrary to the embodiment described with respect to FIG. 2, the crucible 100 can be provided at one end of the vapor distributor 210. For example, the crucible 100 can be provided at a lower end of the vapor distributor 210. The third opening of the vapor guiding compartment of the crucible 100 can be provided at an upper end of the crucible 100 to be in fluid communication with the lower end of the vapor distributor 210.

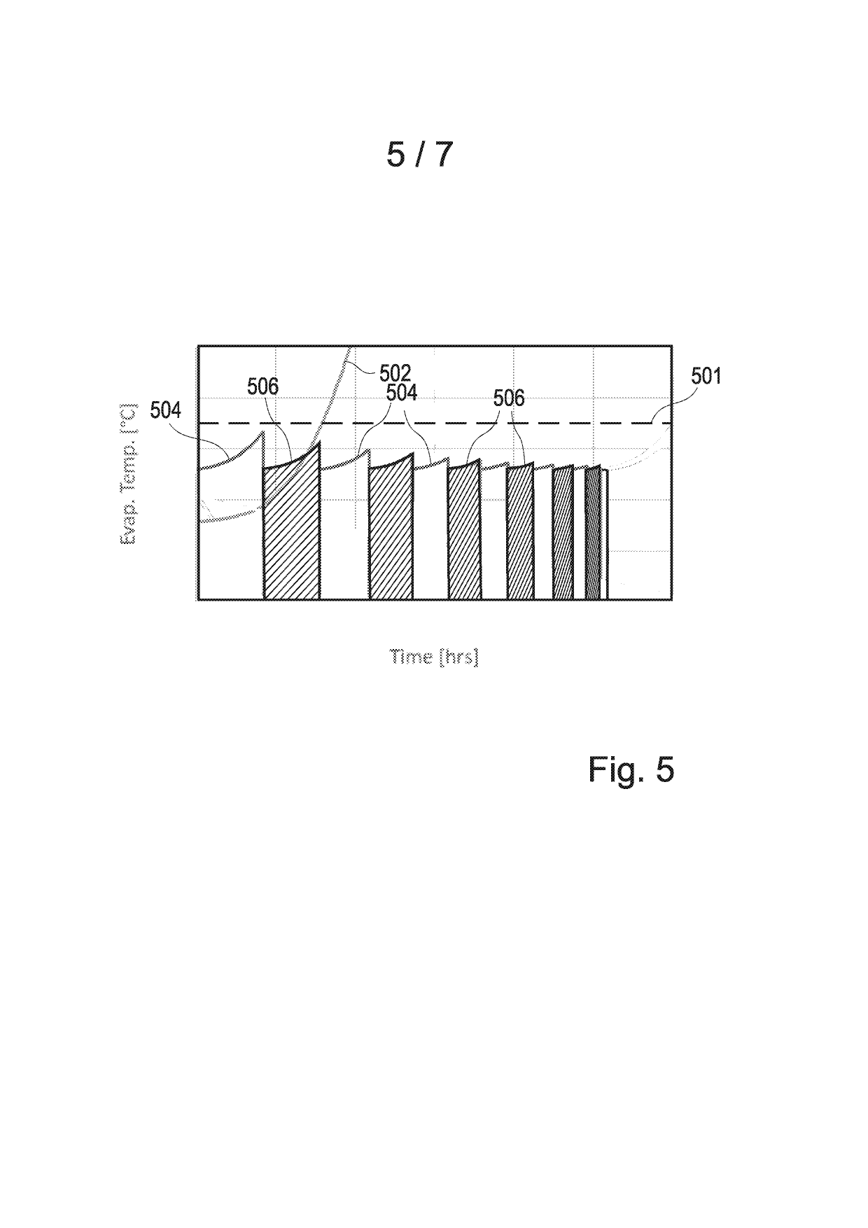

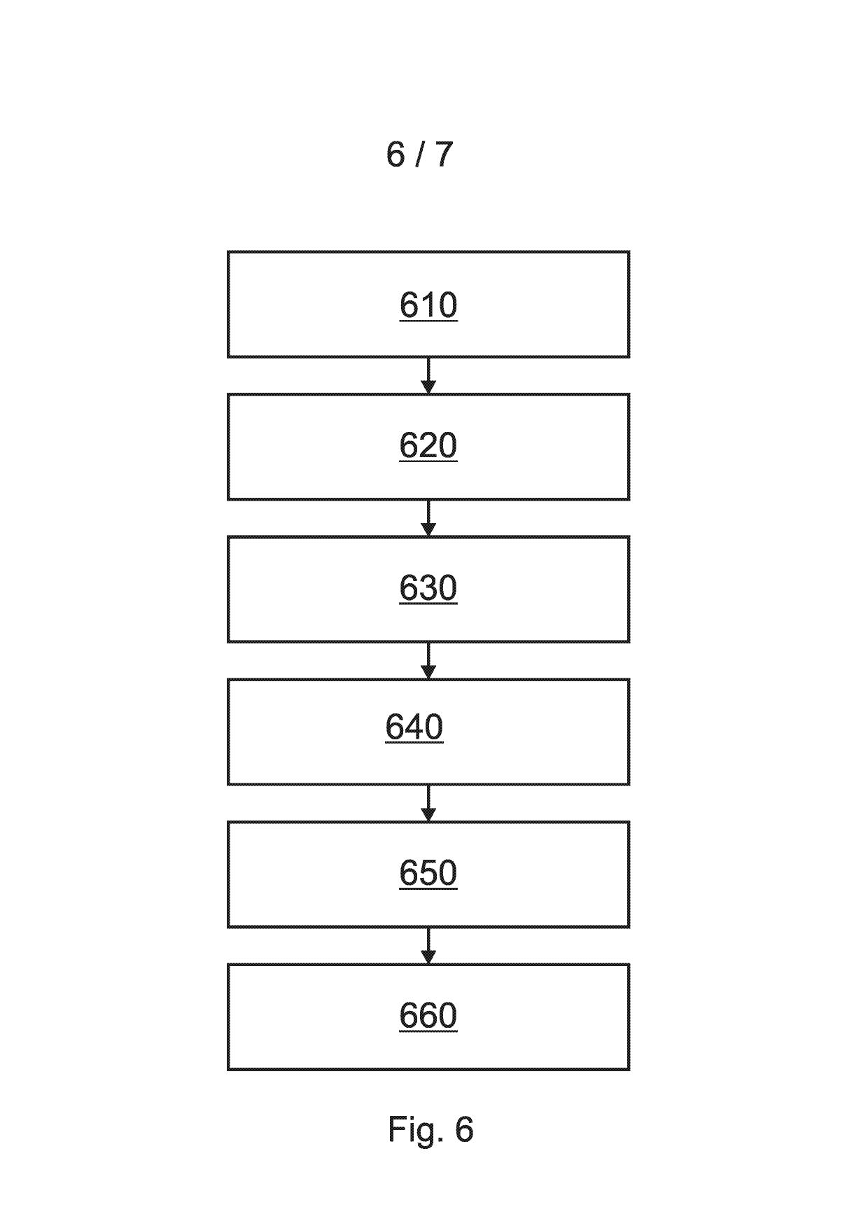

FIGS. 5 and 6 illustrate an evaporation method. FIG. 5 shows graph of the evaporation temperature in the first compartment and the second compartment respectively as a function of the time of operating the crucible. Line 501 shows a temperature limit for the organic material to be evaporated. Line 502 shows the temperature, and particularly the temperature increase for a predetermined evaporation rate of a common crucible. The lines 504 show an evaporation temperature of a first material compartment. The lines 506 having the hatched area show an evaporation temperature of the second material compartment. As shown by the simulation of the evaporation temperatures, for a predetermined evaporation rate, the temperature of the evaporated material in each of the material compartments is below the temperature limit indicated by line 501. Further, in light of the reduced total amount of material in the crucible after several hours of operation of the crucible, the switching frequency for switching between the first material compartment and the second material compartment (and vice versa) increases. Due to the purification process, the temperature for evaporation of the crucible can be maintained below the critical temperature for evaporation to avoid or reduce decomposition of the source material to be evaporated.

FIG. 6 shows an evaporation method. According to operation 610, a source material to be evaporated is provided in a first material compartment of a crucible. Thereafter, the first material compartment is heated, as illustrated by box 620, to evaporate the source material generating evaporated source material while a second material compartment of the crucible is in an idle state. For example, this corresponds to the first portion of line 504 in FIG. 5. The evaporated source material is guided from the first material compartment to a vapor distributor (see operation 630). The portion of the evaporated source material being guided to the vapor distributor is utilized for substrate processing and can be guided on a substrate by the vapor distributor. According to operation 640, the second material compartment is heated to evaporate condensed source material in the second material compartment generating evaporated source material. For example, this corresponds to the first portion of line 506 in FIG. 5, wherein the evaporation temperature of the second material compartment is shown. The evaporated source material is guided from the second material compartment to the vapor distributor (see operation 650). According to operation 660, the first material compartment is switched to an idle state. According to some embodiments, which can be combined with other embodiments described herein, at least one of the material compartments is heated to generate evaporated source material for substrate processing. During a first time period, the first material compartment is heated and the second material compartment is at an idle state. During a second time period, the second material compartment is heated and the first material compartment is at an idle state.

According to some embodiments, which can be combined with other embodiments described herein, a material compartment being at an idle state refers to providing a temperature in the material compartment that allows for condensation of source material in the material compartment. For example, the heater corresponding to the material compartment is switched off and/or the temperature of the material compartment is adjusted to a sufficiently low temperature to allow for compensation in the respective material compartment.

According to some embodiments, which can be combined with other embodiments described herein, an evaporation method further includes heating a vapor guiding compartment being in fluid communication with the first material compartment and with the second material compartment. Heating of the vapor guiding compartment avoids condensation of source material in the vapor guiding compartment and allows for fluid communication between the vapor guiding compartment and the first material compartment, for fluid communication between the vapor guiding compartment and the second material compartment, and for fluid communication between the vapor guiding compartment and the vapor distributor.

As previously described with respect to FIGS. 1A to 1C, after switching the first material compartment to an idle state, the first material compartment is heated (again) to evaporate condensed source material in the first material compartment generating evaporated source material. For example, this corresponds to a second portion of the line 504 shown in FIG. 5. The evaporated source material is guided from the first material compartment to the vapor distributor and the second material compartment is switched (again) to an idle state.

According to some embodiments, which can be combined with other embodiments described herein, a crucible, an evaporation source, or a vacuum processing system may further include a controller 150 as exemplarily shown in FIG. 1A. The controller 150 can be connected to the heaters. The controller 150 comprises a central processing unit (CPU), a memory and, for example, support circuits. To facilitate control of the evaporation, the CPU may be one of any form of general-purpose computer processor that can be used in an industrial setting for controlling various chambers and sub-processors. The memory is coupled to the CPU. The memory, or a computer readable medium, may be one or more readily available memory devices such as random-access memory, read only memory, hard disk, or any other form of digital storage either local or remote. The support circuits may be coupled to the CPU for supporting the processor in a conventional manner. These circuits include cache, power supplies, clock circuits, input/output circuitry and related subsystems, and the like. Evaporation process instructions are generally stored in the memory as a software routine typically known as a recipe. The software routine may also be stored and/or executed by a second CPU (not shown) that is remotely located from the hardware being controlled by the CPU. The software routine, when executed by CPU, transforms the general-purpose computer into a specific purpose computer (controller) that controls the evaporation, e.g. the heaters of the crucible. Although the method and/or process of the present disclosure is discussed as being implemented as a software routine, some of the method operations that are disclosed therein may be performed in hardware as well as by the software controller. As such, the invention may be implemented in software as executed upon a computer system, and in hardware as an application specific integrated circuit or other type of hardware implementation, or a combination of software and hardware. The controller may execute or perform an evaporation method according to embodiments of the present disclosure and as exemplarily described with respect to FIGS. 1A to 1C, FIG. 5 and FIG. 6.

According to an embodiment, an evaporation source is provided. The evaporation source includes a crucible and a controller having a processor and a memory storing instructions that, when executed by the processor, cause the evaporation source to perform a method according to embodiments described herein.

According to a further embodiment, a method of manufacturing device having a layer of organic material is provided. The method includes operating a crucible according to embodiments of the present disclosure and depositing a layer of organic material on a substrate.

Embodiments described herein divide the source material in the loading area having at least two portions, for example, a first material compartment as described herein and a second material compartment as described herein. The portions of the loading area have dedicated heaters for each of the material compartments. At an initial state, material is filled in at least one of the material compartments. One material compartment, for example, the material compartment with the higher material filling amount is provided in an active state. The material compartment is heated. The temperature of the material compartment is provided to have a predetermined deposition rate on a substrate to be processed. A portion of the evaporated material will condense in the other portion of the loading area, i.e. that material compartment being in an idle state during evaporation based on heating the active material compartment. In light of the purification process, the condensed material is at least as pure as the material reaching the substrate. The effect of polymerization or oxidation in the compartment receiving the condensed source material, which may be based on previous evaporation in this compartment, is reduced. When the heater temperature of the active material compartment gets close to the limit temperature or the material in the active one gets close to empty, the active portion will be switched to the other portion of the loading area, particularly with a smooth transition. For example, an intermediate operation condition (see FIG. 1B) with both heaters of the first material compartment and the second material compartment being active can be provided. Even if a “skin” is created, this condition will be covered by “pure” material from neighbor portion. Because of the “in-situ purification” process, the temperature to get a certain deposition rate can be set back to the initial condition when switching the active portion from one material compartment to another material compartment.

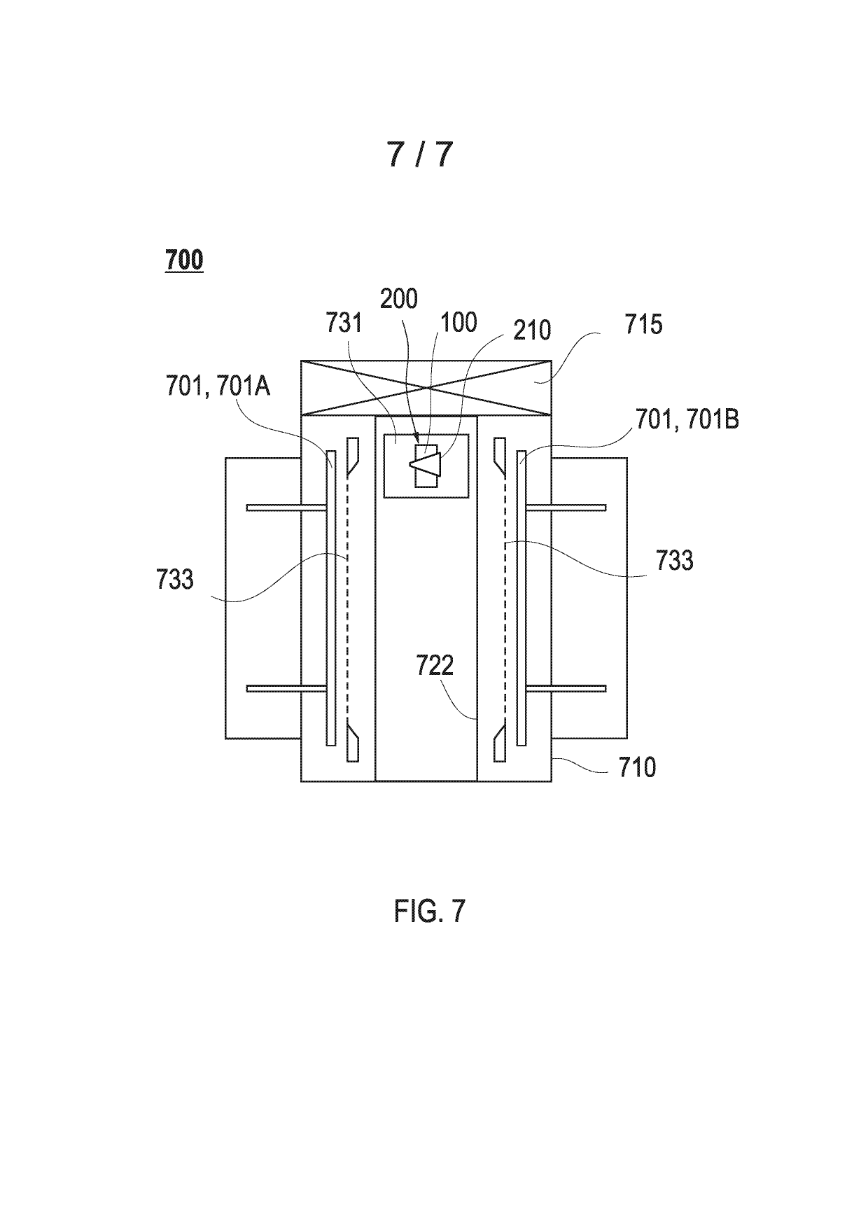

According to an aspect of the present disclosure, a vacuum deposition system 700 is provided, as exemplarily shown in FIG. 7. The vacuum deposition system includes a vacuum deposition chamber 710, an evaporation source according to any of the embodiments described herein in the vacuum deposition chamber 710, and a substrate support configured for supporting a substrate 701 during material deposition.

In particular, the evaporation source 200 can be provided on a track or linear guide 722, as exemplarily shown in FIG. 7. The linear guide 722 may be configured for the translational movement of the evaporation source 200. Further, a drive for providing a translational movement of the evaporation source 200 can be provided. In particular, a transportation apparatus for contactless transportation of the evaporation source 200 may be provided in the vacuum deposition chamber. As exemplarily shown in FIG. 7, the vacuum deposition chamber 710 may have a gate valve 715 via which the vacuum deposition chamber can be connected to an adjacent routing module. The routing module can be configured to transport the substrate to a further vacuum deposition system for further processing.

With exemplary reference to FIG. 7, according to embodiments which can be combined with any other embodiment described herein, two substrates, e.g. a first substrate 701A and a second substrate 701B, can be supported on respective transportation tracks within the vacuum deposition chamber 710. Further, two tracks for providing masks 733 thereon can be provided.

With exemplary reference to FIG. 7, a source support 731 configured for the translational movement of the evaporation source 200 along the linear guide 722 may be provided. The source support 731 supports a crucible 100 and a vapor distributor 210 provided e.g. over the evaporation crucible, as schematically shown in FIG. 7. Accordingly, the vapor generated in the evaporation crucible can move upwardly and out of the one or more outlets of the distribution pipe. Accordingly, as described herein, the distribution pipe is configured for providing evaporated material, particularly a plume of evaporated organic material, from the vapor distributor to the substrate 701.

According to an embodiment, a vacuum deposition system is provided. The vacuum deposition system includes a vacuum deposition chamber and an evaporation source according to any of the embodiments described herein. Particularly, a crucible with a first material compartment and a second material compartment according to embodiments described herein is provided. A substrate support is configured for supporting a substrate during material deposition, particularly in an essentially vertical orientation.

In the present disclosure, a “vacuum deposition system” is to be understood as a vacuum chamber configured for vacuum deposition, wherein one or more evaporation sources as described herein may be arranged in the vacuum chamber. The term “vacuum”, as used herein, can be understood in the sense of a technical vacuum having a vacuum pressure of less than, for example, 10 mbar. Typically, the pressure in a vacuum chamber as described herein may be between 10-5 mbar and about 10-8 mbar, more typically between 10-5 mbar and 10-7 mbar, and even more typically between about 10-6 mbar and about 10-7 mbar.

While the foregoing is directed to embodiments of the disclosure, other and further embodiments of the disclosure may be devised without departing from the basic scope thereof, and the scope thereof is determined by the claims that follow.

In particular, this written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. An evaporation method, comprising:
providing a source material to be evaporated in a first material compartment of a crucible;
heating the first material compartment to evaporate the source material generating an evaporated source material while a second material compartment of the crucible is in an idle state;
guiding the evaporated source material from the first material compartment to a vapor distributor;
heating the second material compartment to evaporate a condensed source material in the second material compartment generating evaporated source material;
guiding the evaporated source material from the second material compartment to the vapor distributor; and
switching the first material compartment to the idle state.

2. The evaporation method according to claim 1, further comprising, while heating the first material compartment to evaporate the source material generating the evaporated source material while the second material compartment of the crucible is in the idle state:
guiding the evaporated source material from the first material compartment to the second material compartment; and
condensing the evaporated source material in the second material compartment.

3. The evaporation method according to claim 1, further comprising:
after switching the first material compartment to the idle state, heating the first material compartment to evaporate the condensed source material in the first material compartment generating the evaporated source material;
guiding the evaporated source material from the first material compartment to the vapor distributor; and
switching the second material compartment to the idle state.

4. The evaporation method according to claim 1, further comprising, after switching the first material compartment to the idle state:
guiding the evaporated source material from the second material compartment to the first material compartment while the first material compartment is in the idle state; and
condensing the evaporated source material in the first material compartment while the first material compartment is in the idle state.

5. The evaporation method according to claim 1, further comprising:
heating a vapor guiding compartment being in fluid communication with the first material compartment and with the second material compartment.

6. The evaporation method according to claim 5, wherein the first material compartment and the second material compartment are arranged outside the vapor guiding compartment.

7. The evaporation method according to claim 1, wherein the idle state of the first material compartment and the second material compartment refers to a state, in which a temperature is provided in the respective material compartment that allows for condensation of the evaporated source material in the respective material compartment.

8. The evaporation method according to claim 1, further comprising:
controlling and/or adjusting a ratio between a deposition rate on a substrate and a purification speed of purifying the evaporated source material by condensation of the evaporated source material in the idle state of the first material compartment or in the idle state of the second material compartment, wherein the ratio is controlled and/or adjusted using at least one of a partition wall and an orifice of the crucible.

9. The evaporation method according to claim 8, wherein the crucible comprises a vapor guiding compartment having a first opening providing a first fluid communication path between the first material compartment and the vapor guiding compartment and having a second opening providing a second fluid communication path between the second material compartment and the vapor guiding compartment, and wherein the at least one of the partition wall and the orifice comprises:
at least one of a first orifice in the first fluid communication path and a second orifice in the second fluid communication path.

10. The evaporation method according to claim 8, wherein the crucible comprises a vapor guiding compartment having a first opening providing a first fluid communication path between the first material compartment and the vapor guiding compartment and having a second opening providing a second fluid communication path between the second material compartment and the vapor guiding compartment, and wherein the at least one of the partition wall and the orifice comprises:
the partition wall provided in the vapor guiding compartment to define a fluid conductance between the first material compartment and the second material compartment.

11. The evaporation method according to claim 10, wherein the partition wall has an opening.

12. An evaporation method of claim 1, further comprising:
guiding the evaporated source material through a third opening disposed within a vapor guiding compartment;
guiding the evaporated source material through the vapor distributor, the vapor distributor in fluid communication with the crucible; and
depositing a layer of organic material on a substrate.

13. An evaporation method, comprising:
heating a first material compartment to evaporate a source material generating evaporated source material while a second material compartment of a crucible is in an idle state;
guiding at least a first portion of the evaporated source material from the first material compartment to a vapor distributor and at least a second portion of the evaporated source material to the second material compartment in the idle state;
condensing the second portion of the evaporated source material to form a condensed source material within the second material compartment in the idle state;
heating the second material compartment to evaporate the condensed source material in the second material compartment to generate the evaporated source material;
guiding the evaporated source material from the second material compartment to the vapor distributor; and
switching the first material compartment to the idle state.

14. The evaporation method of claim 13, wherein the first material compartment is heated by a first heater and the second material compartment is heated by a second heater.

15. The evaporation method of claim 13, further comprising guiding a portion of the evaporated source material through a vapor guiding compartment that is disposed outside of the first material compartment and the second material compartment, wherein the vapor guiding compartment is in fluid connection with the first material compartment and the second material compartment.

16. The evaporation method of claim 14, wherein the first material compartment comprises a first opening and the second material compartment comprises a second opening, wherein a first orifice is disposed over the first opening and a second orifice is disposed over the second opening such that the first orifice and the second orifice are operable to adjust a purification speed.

17. An evaporation method, comprising:
heating a first material compartment to evaporate a source material generating evaporated source material while a second material compartment of a crucible is in an idle state;
guiding the evaporated source material through a first opening disposed over the first material compartment and into a vapor guiding compartment, wherein the vapor guiding compartment is in fluid connection with the first material compartment and the second material compartment and the vapor guiding compartment comprises a third opening;
guiding at least a first portion of the evaporated source material from the vapor guiding compartment through the third opening to a vapor distributor and at least a second portion of the evaporated source material through a second opening to the second material compartment in the idle state;
condensing the second portion of the evaporated source material to form a condensed source material within the second material compartment in the idle state;
heating the second material compartment to evaporate the condensed source material in the second material compartment to generate the evaporated source material;
guiding the evaporated source material from the second material compartment to the vapor distributor; and
switching the first material compartment to the idle state.

18. The evaporation method of claim 17, wherein the vapor guiding compartment further comprises a partition wall, the partition wall comprising one or more openings, the partition wall operable to adjust a purification speed.

19. The evaporation method of claim 17, wherein the first material compartment is heated by a first heater, the second material compartment is heated by a second heater, and the vapor guiding compartment is heated by a third heater.

20. The evaporation method of claim 19, wherein the first heater, the second heater, and the third heater are operable to be independently operated.
